(19) United States
(12) Patent Application Publication
(10) Pub. No.: US 2018/0315722 A1
(43) Pub. Date: Nov. 1, 2018

(54) SEMICONDUCTOR DEVICE AND MANUFACTURING METHOD THEREOF

(71) Applicant: RENESAS ELECTRONICS CORPORATION, Tokyo (JP)

(72) Inventors: Akira YAJIMA, Ibaraki (JP); Yoshiaki YAMADA, Ibaraki (JP)

(21) Appl. No.: 15/937,028

(22) Filed: Mar. 27, 2018

(30) Foreign Application Priority Data
Apr. 28, 2017 (JP) 2017-089345

(51) Int. Cl. H01L 23/00; H01L 21/66; G11C 29/50

(52) U.S. Cl. CPC H01L 24/05; G11C 2029/0403; H01L 24/11; H01L 22/14; G11C 29/50016; H01L 2224/0401; H01L 2224/05025; H01L 2224/05083; H01L 2224/05124; H01L 2224/05166; H01L 2924/04941; H01L 2224/05147; H01L 2224/13026; H01L 2224/13139; H01L 2224/13144; H01L 2224/13164; H01L 2224/13564; H01L 2924/014; H01L 2224/13611; H01L 2224/13639; H01L 2224/13647; H01L 2224/117; H01L 2224/11849; H01L 2224/11462; H01L 2224/1132; H01L 2924/14511; H01L 24/13

(57) ABSTRACT

A barrier layer BAL is formed so as to be in contact with an aluminum pad ALP. A titanium alloy layer including a titanium film and a titanium nitride film is formed as barrier layer BAL. A seed layer SED is formed so as to be in contact with barrier layer BAL. A copper film is formed as seed layer SED. A silver bump AGBP is formed so as to be in contact with seed layer SED. Silver bump AGBP is constructed with a silver film AGPL formed by an electrolytic plating method. A tin alloy ball SNB is bonded to silver bump AGBP.

This nonprovisional application is based on Japanese Patent Application No. 2017-089345 filed on Apr. 28, 2017 with the Japan Patent Office, the entire contents of which are hereby incorporated by reference.

### BACKGROUND OF THE INVENTION

### Field of the Invention

The present invention relates to a semiconductor device and a method for manufacturing the semiconductor device, and for example, it can be suitably used for a semiconductor device including a solder ball.

### Description of the Background Art

The semiconductor device is required to have resistance according to an environment where the semiconductor device is used. For example, an automotive semiconductor device is required to have desired heat resistance. In order to satisfy requirements of the heat resistance, for example, the semiconductor device is subjected to a temperature cycle test and a high temperature exposure test. The temperature cycle test is one in which a test that operates the semiconductor device under an environment in which a temperature is sequentially changed within a predetermined temperature range is repeated a predetermined number of times. The high temperature exposure test is one in which the semiconductor device is operated for a predetermined time under a predetermined high temperature environment.

In the automotive semiconductor device, because a flash memory is mounted for the purpose of control, a memory retention test is further performed on the flash memory. In the memory retention test, for example, whether information (memory) stored in the flash memory disappears is determined by performing baking (retention bake) at 250° C. for about 8 hours.

On the other hand, in the semiconductor device, there is a demand for a package structure excellent in a heat radiation characteristic and heat resistance, and flip-chip connection is adopted as one of techniques of connecting the semiconductor device and a substrate. For example, Patent Document 1 (Japanese Patent Laying-Open No. 2008-172232) and Non-Patent Document 1 (Hiroshi Manita: “The Electroplated Wafer Bumping Technology-The Gold and Solder Bump Process”, Journal of Japan Institute of Electronics Packaging, Vol. 1, No. 5 (1998)) disclose this kind of semiconductor device. In the flip-chip connection, the semiconductor device is connected to the substrate while bumps previously connected to pads of the semiconductor chip (die) are interposed therebetween. A solder ball is applied as the bump.

### SUMMARY OF THE INVENTION

As described above, various tests including the memory retention test, the temperature cycle test, and the high temperature exposure test are performed in the automotive semiconductor device. In particular, for example, the memory retention test is performed at a temperature of 250° C.

However, in the semiconductor device in which the solder ball is applied as the bump, the memory retention test cannot be performed because the solder is melted. Consequently, in the semiconductor device to which the solder ball is applied, there is a demand for a bump structure that can be subjected to tests such as the memory retention test.

Other problems and novel features will be apparent from the description of the specification and the accompanying drawings.

A semiconductor device according to one embodiment includes an element formation region, a semiconductor element, a multilayer interconnect structure, a pad electrode, a barrier layer, a silver bump, and a solder bump. The element formation region is defined in a semiconductor substrate. The semiconductor element is formed in the element formation region. The multilayer interconnect structure is formed so as to cover the semiconductor element, and includes a plurality of interconnect layers and an interlayer dielectric that electrically insulates the plurality of interconnect layers from each other. The pad electrode is electrically connected to one of the plurality of interconnect layers. The barrier layer is formed so as to be in contact with the pad electrode. The silver bump is electrically connected to the pad electrode with the barrier layer interposed therebetween. The solder bump is formed so as to be in contact with the silver bump.

A semiconductor device manufacturing method according to another embodiment includes the following steps. An element formation region is defined in a semiconductor substrate. A semiconductor element is formed in the element formation region. A multilayer interconnect structure including a plurality of interconnect layers and an interlayer dielectric electrically insulating the plurality of interconnect layers from each other is formed so as to cover the semiconductor element. A pad electrode electrically connected to one of the plurality of interconnect layers is formed. A barrier layer is formed so as to be in contact with the pad electrode. A silver bump electrically connected to the pad electrode is formed with the barrier layer interposed therebetween. A solder bump is formed in the silver bump.

The memory retention test can be performed in the semiconductor device according to one embodiment.

The solder bump that allows testing of the semiconductor element can be formed by the semiconductor device manufacturing method according to another embodiment.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view schematically illustrating an example of a planar structure of a semiconductor device according to a first embodiment.

FIG. 2 is a sectional view taken along a section line II-II in FIG. 1 of the first embodiment.

FIG. 3 is a partially enlarged sectional view illustrating an example of a structure of a memory cell of a flash memory in FIG. 2 of the first embodiment.

FIG. 4 is a manufacturing flowchart of the semiconductor device of the first embodiment.

FIG. 5 is a sectional view illustrating one step of a method for manufacturing the semiconductor device of the first embodiment.

FIG. 6 is a sectional view illustrating a step performed after the step in FIG. 5 of the first embodiment.

FIG. 7 is a sectional view illustrating a step performed after the step in FIG. 6 of the first embodiment.

FIG. 8 is a sectional view illustrating a step performed after the step in FIG. 7 of the first embodiment.

FIG. 9 is a sectional view illustrating a step performed after the step in FIG. 8 of the first embodiment.

FIG. 10 is a sectional view illustrating a step performed after the step in FIG. 9 of the first embodiment.

FIG. 11 is a sectional view illustrating a step performed after the step in FIG. 10 of the first embodiment.

FIG. 12 is a sectional view illustrating a step performed after the step in FIG. 11 of the first embodiment.

FIG. 13 is a sectional view illustrating a step performed after the step in FIG. 12 of the first embodiment.

FIG. 14 is a sectional view illustrating one step of a method for manufacturing a semiconductor device according to a comparative example.

FIG. 15 is a sectional view illustrating a step performed after the step in FIG. 14.

FIG. 16 is a sectional view illustrating a step performed after the step in FIG. 15.

FIG. 17 is a sectional view illustrating a step performed after the step in FIG. 16.

FIG. 18 is a sectional view illustrating a step performed after the step in FIG. 17.

FIG. 19 is a sectional view illustrating a step performed after the step in FIG. 18.

FIG. 20 is a sectional view illustrating a step performed after the step in FIG. 19. FIG. 21 is a sectional view illustrating a step performed after the step in FIG. 20.

FIG. 22 is a sectional view illustrating a step performed after the step in FIG. 21.

FIG. 23 is a phase diagram illustrating a binary alloy of silver and copper in the first embodiment.

FIG. 24 is a first graph illustrating a relationship between an annealing time and a thickness of an intermetallic layer in the first embodiment.

FIG. 25 is a second graph illustrating a relationship between the annealing time and the thickness of the intermetallic layer in the first embodiment.

FIG. 26 is a third graph illustrating the relationship between the annealing time and the thickness of the intermetallic layer in the first embodiment.

FIG. 27 is a table illustrating physical properties for describing hardness of each material in the first embodiment.

FIG. 28 is a graph illustrating a relationship between a contact area and a contact resistance in the first embodiment.

FIG. 29 is a manufacturing flowchart of the semiconductor device according to a second embodiment.

FIG. 30 is a sectional view illustrating one step of a method for manufacturing the semiconductor device of the second embodiment.

FIG. 31 is a sectional view illustrating a step performed after the step in FIG. 30 of the second embodiment.

FIG. 32 is a sectional view illustrating a step performed after the step in FIG. 31 of the second embodiment.

FIG. 33 is a sectional view illustrating a step performed after the step in FIG. 32 of the second embodiment.

FIG. 34 is a sectional view illustrating a step performed after the step in FIG. 33 of the second embodiment.

FIG. 35 is a sectional view illustrating a step performed after the step in FIG. 34 of the second embodiment.

FIG. 36 is a sectional view illustrating a step performed after the step in FIG. 35 of the second embodiment.

FIG. 37 is a sectional view illustrating a step performed after the step in FIG. 36 of the second embodiment.

FIG. 38 is a sectional view illustrating a step performed after the step in FIG. 37 of the second embodiment.

FIG. 39 is a manufacturing flowchart of a semiconductor device according to a third embodiment.

FIG. 40 is a sectional view illustrating one step of a method of manufacturing the semiconductor device of the third embodiment.

FIG. 41 is a sectional view illustrating a step performed after the step in FIG. 40 of the third embodiment.

FIG. 42 is a sectional view illustrating a step performed after the step in FIG. 41 of the third embodiment.

FIG. 43 is a sectional view illustrating a step performed after the step in FIG. 42 of the third embodiment.

FIG. 44 is a sectional view illustrating a step performed after the step in FIG. 43 of the third embodiment.

FIG. 45 is a sectional view illustrating a step performed after the step in FIG. 44 of the third embodiment.

FIG. 46 is a sectional view illustrating a step performed after the step in FIG. 45 of the third embodiment.

FIG. 47 is a sectional view illustrating a step performed after the step in FIG. 46 of the third embodiment.

FIG. 48 is a sectional view illustrating a step performed after the step in FIG. 47 of the third embodiment.

FIG. 49 is a sectional view illustrating a step performed after the step in FIG. 48 of the third embodiment.

FIG. 50 is a sectional view illustrating a step performed after the step in FIG. 49 of the third embodiment.

### DESCRIPTION OF THE PREFERRED EMBODIMENTS

### First Embodiment

A first example of a semiconductor device including a silver bump and a tin alloy ball (solder bump) as a bump structure will be described below.

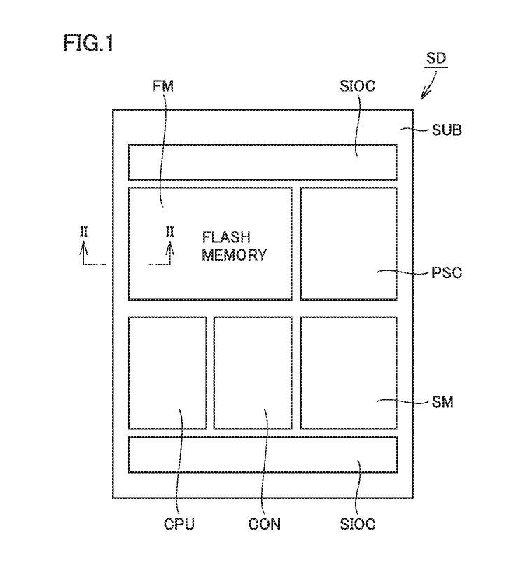

First, an example of an overall configuration of the semiconductor device will be described. As illustrated in FIG. 1, a plurality of circuits each of which has a predetermined function are formed in a semiconductor device SD. For example, a power supply circuit PSC, a signal input and output circuit SIOC, a DA-AD converter CON, a static random access memory SM, a flash memory FM, and a central processing unit CPU are arranged as the plurality of circuits on a semiconductor substrate SUB. A plurality of element formation regions are defined in semiconductor substrate SUB, and a predetermined semiconductor element corresponding to the circuit is formed in each of the element formation regions.

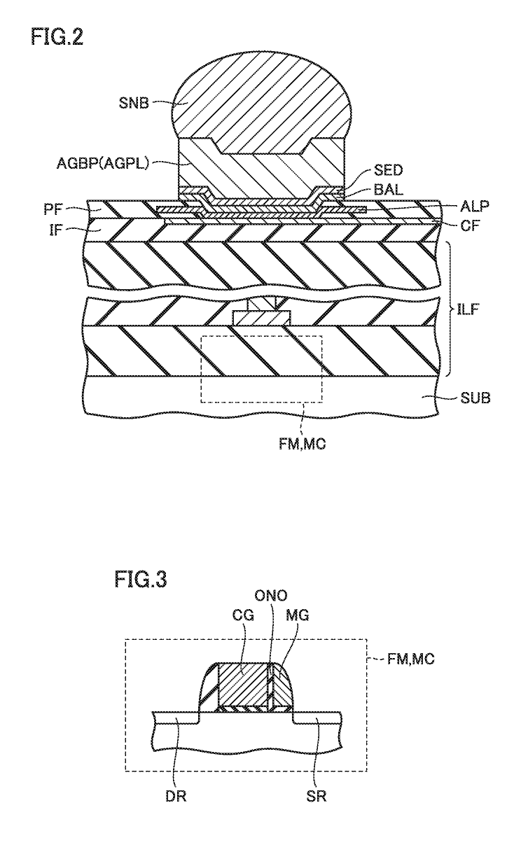

A sectional structure of the element formation region where flash memory FM is disposed will be described as an example of a sectional structure of the semiconductor device. As illustrated in FIG. 2, a memory cell MC of flash memory FM is formed in the region of semiconductor substrate SUB on which flash memory FM is disposed. As illustrated in FIG. 3, memory cell MC includes a control gate electrode CG, a memory gate electrode MG, a source region SR, and a drain region DR.

Memory gate electrode MG is formed on one of side surfaces of control gate electrode CG with an insulator ONO interposed therebetween. Insulator ONO is constructed with a silicon oxide film and a laminated film in which silicon nitride film and the silicon oxide film are laminated. This kind of memory cell MC is called a Metal-Oxide-Nitride-Oxide-Silicon (MONOS) type, and in particular it is called a Flash-Metal-Oxide-Nitride-Oxide-Silicon (FMONOS) type in the case of flash memory FM.

As illustrated in FIG. 2, a multilayer interconnect structure ILF including a plurality of interconnect layers and an interlayer dielectric insulating the plurality of interconnect layers from each other is formed so as to cover memory cell MC. Further, An insulator IF is further formed so as to cover multilayer interconnect structure ILF. Copper wiring CF is formed in insulator IF. An aluminum pad ALP is formed so as to be in contact with copper wiring CF. An insulator PF is formed so as to cover aluminum pad ALP.

A barrier layer BAL is formed so as to penetrate insulator PF to come into contact with aluminum pad ALP. A titanium alloy layer having a thickness of 70 nm or more is formed as barrier layer BAL, the titanium alloy layer including a titanium film and a titanium nitride film. A seed layer SED is formed so as to be in contact with barrier layer BAL. A copper film having a thickness of 100 nm or more is formed as seed layer SED.

A silver bump AGBP is formed so as to be in contact with seed layer SED. Silver bump AGBP is constructed with a silver film AGPL formed by an electrolytic plating method. A tin alloy ball SNB that is of the solder bump is bonded to silver bump AGBP.

A bump structure including silver bump AGBP to which tin alloy ball SNB is bonded is electrically connected to, for example, memory cell MC through predetermined interconnect (not illustrated) in multilayer interconnect structure ILF. A main part of the semiconductor device including silver bump AGBP and tin alloy ball SNB is configured as described above.

An example of a method for manufacturing the semiconductor device will be described below. First, a manufacturing flowchart will be explained.

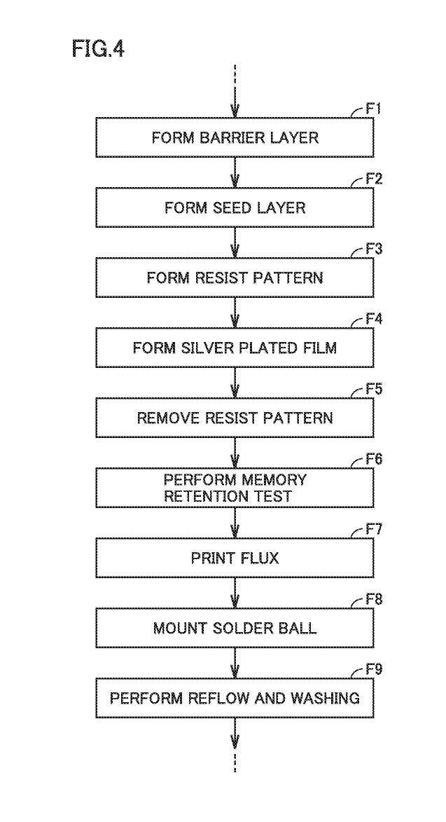

First, a structure including the memory cell, the multilayer interconnect structure, the copper wiring, and the aluminum pad is formed on a semiconductor substrate. Then, in step F1, the barrier layer is formed so as to be in contact with the aluminum pad as illustrated in FIG. 4. Then, in step F2, the seed layer is formed so as to be in contact with the barrier layer. Then, in step F3, a resist pattern is formed in order to form the silver bump.

Then, in step F4, a silver plated film is formed on an exposed portion of the seed layer by the electrolytic plating method. In step F5, the resist pattern is removed. Then, in step F6, a memory retention test is performed. Then, in step F7, a flux is printed on the silver plated film. Then, in step F8, the solder ball is mounted on the silver plated film. Then, in step F9, reflow and washing are performed. Then, the semiconductor device is completed through a temperature cycle test and a high temperature exposure test.

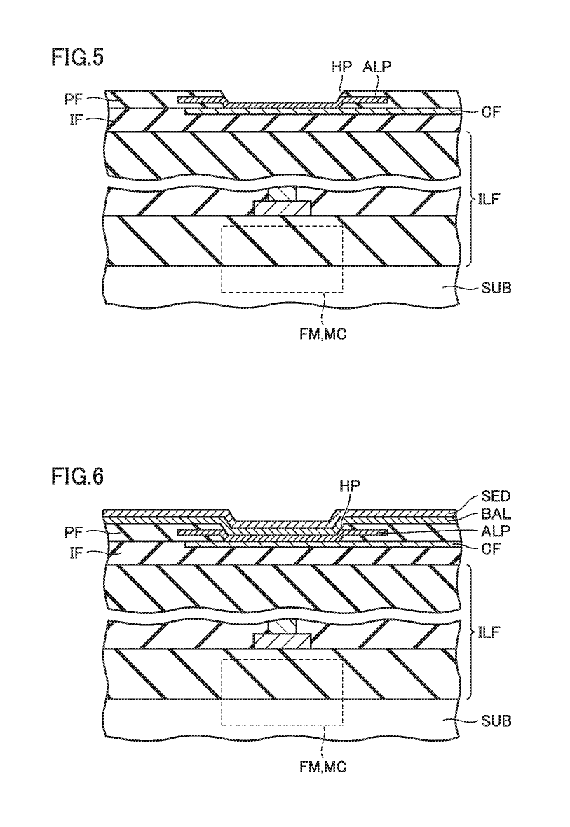

The semiconductor device manufacturing method will specifically be described below while the sectional structure is illustrated. As illustrated in FIG. 5, the semiconductor element including memory cell MC of flash memory FM is formed on semiconductor substrate SUB. Then, multilayer interconnect structure ILF is formed so as to cover memory cell MC. Then, for example, insulator IF constructed with a low-k film is formed. Then, copper wiring CF is formed in insulator IF by a damascene method.

Then, aluminum pad ALP is formed so as to be in contact with copper wiring CF. Insulator PF is formed so as to cover aluminum pad ALP. Then, an opening HP through which aluminum pad ALP is exposed is formed in insulator PF by performing a predetermined photomechanical process and etching process.

Then, as illustrated in FIG. 6, a titanium film (a thickness of about 10 nm), a titanium nitride film (a thickness of about 50 nm) and a titanium film (a thickness of about 10 nm) are sequentially formed so as to be in contact with exposed aluminum pad ALP by a sputtering method, thereby forming barrier layer BAL made of the titanium alloy layer (a thickness of about 70 nm or more).

Then, a copper film (a thickness of 100 nm or more) is formed by the sputtering method so as to be in contact with barrier layer BAL, thereby forming seed layer SED. The seed layer is not limited to a copper film as long as the film has a relatively low electrical resistance. For example, a silver film may be formed by the sputtering method.

Then, in order to form a silver plated film, a resist pattern PR1 is formed by performing a predetermined photomechanical process as illustrated in FIG. 7. For example, an opening diameter of resist pattern PR1 is set to about 80 μm so as to correspond to a pattern of an under bump metal (UBM). For example, the thickness of resist pattern PR1 is set to 12 μm or more.

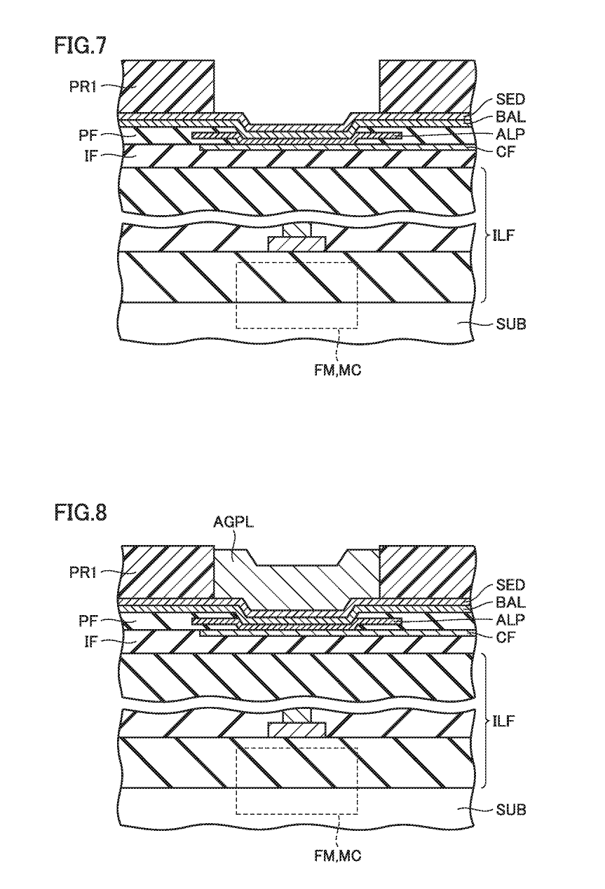

Then, as illustrated in FIG. 8, silver is grown on a surface of exposed seed layer SED by the electrolytic plating method, thereby forming silver film AGPL (silver plated film). Before the electrolytic plating, the surface of exposed seed layer SED may be exposed to an oxygen plasma atmosphere as a pretreatment. The surface of exposed seed layer SED may be subjected to a desmear treatment using a desmear chemical.

Then, resist pattern PR1 is removed. After resist pattern PR1 is removed, the surface of exposed seed layer SED may be exposed to the oxygen plasma atmosphere as an after-treatment. The surface of exposed seed layer SED may be subjected to a desmear treatment using a desmear chemical.

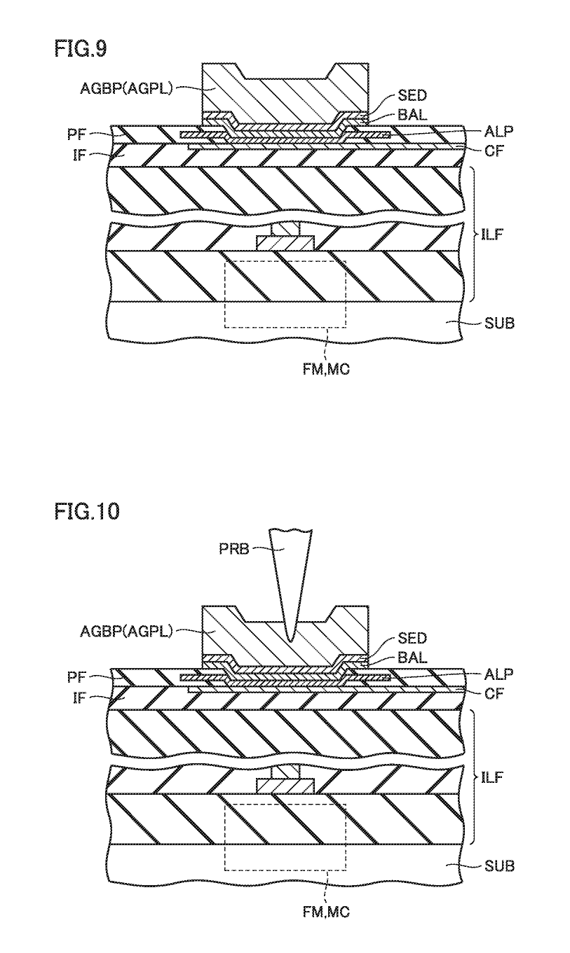

Then, as illustrated in FIG. 9, exposed seed layer SED and barrier layer BAL are sequentially removed by performing the etching process. Thus, silver bump AGBP constructed with silver film AGPL (a thickness of about 16 μm) is formed.

Then, the memory retention test is performed on the flash memory. As illustrated in FIG. 10, a probe needle PRB is brought into contact with silver bump AGBP to write information in memory cell MC of flash memory FM. For example, a charge is accumulated as information in insulator ONO (silicon nitride film) by applying predetermined voltages to control gate electrode CG, memory gate electrode MG, source region SR, and drain region DR in FIG. 3 (source side injection).

Then, a heat treatment (retention bake is performed at a temperature of 250° C. for 8 hours twice) is performed on semiconductor substrate SUB in which the information is written in flash memory FM. A retention test for testing whether the information written in the flash memory is retained is performed after the heat treatment. Predetermined voltages different from the voltages during the writing are applied to control gate electrode CG, memory gate electrode MG, source region SR, and drain region DR in FIG. 3.

At this point, when a threshold voltage of the transistor including memory gate electrode MG is higher than the predetermined voltage, it is determined that the state in which the information is written is retained. On the other hand, when the threshold voltage is lower than the predetermined voltage, it is determined that the written information disappears. A series of steps of the heat treatment and information reading are repeated plural times as necessary. Then, if necessary, a wafer test may be performed by bringing another probe needle (not illustrated) into contact with predetermined silver bump AGBP. The wafer test may be performed before the memory retention test.

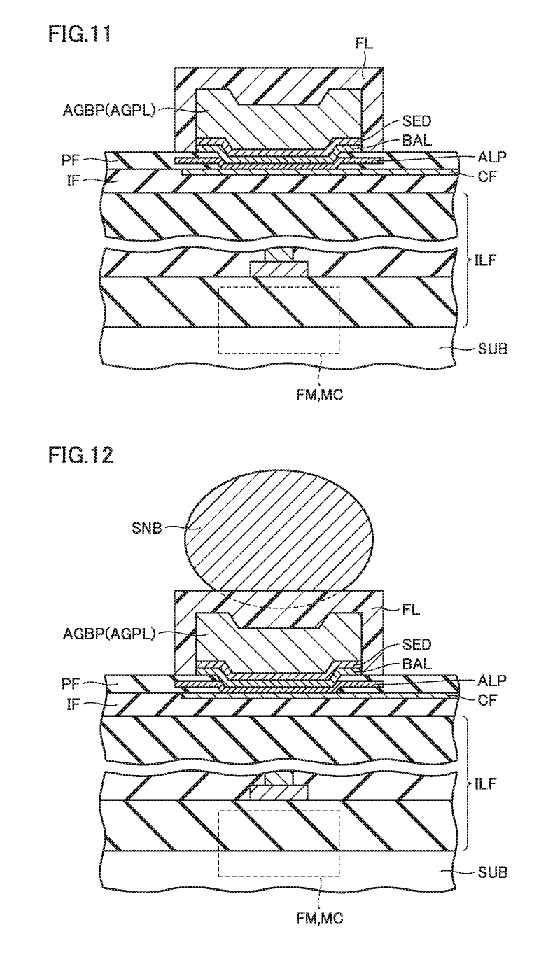

Then, a flux FL is applied, for example, by a printing method so as to cover silver bump AGBP as illustrated in FIG. 11. Then, tin alloy ball SNB (Sn-1.0% Ag-0.5% Cu) having a size of about 100 μm is mounted on silver bump AGBP as illustrated in FIG. 12. An alignment mask in which openings are provided to align minute balls (tin alloy balls SNB) is used when tin alloy ball SNB is mounted.

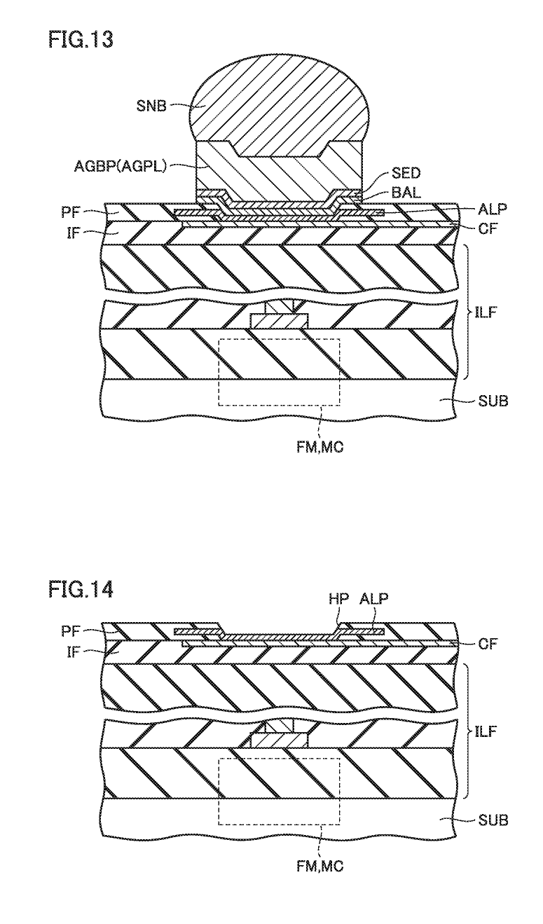

Then, as illustrated in FIG. 13, tin alloy ball SNB is bonded to silver bump AGBP by performing the heat treatment at a temperature slightly higher than a melting point of tin alloy ball SNB. Then, semiconductor substrate SUB including tin alloy ball SNB is washed. Thus, the main part of the semiconductor device is completed.

Then, the semiconductor device is mounted on a predetermined substrate, and subjected to the temperature cycle test and the high temperature exposure test. In the temperature cycle test, for example, a temperature is set to a range from about −65° C. to about 150° C. For example, the number of repetitions is set to about 2000 times. In the high temperature exposure test, for example, a temperature is set to about 150° C. For example, time is set to about 6000 hours. These numerical values are only by way of example.

In the semiconductor device, silver bump AGBP is formed, which allows the memory retention test of the flash memory to be performed before tin alloy ball SNB is formed. This will be described in comparison with a method for manufacturing a semiconductor device according to a comparative example. The same component as that of the semiconductor device of the first embodiment is denoted by the same reference numeral, and the description will be omitted unless necessary.

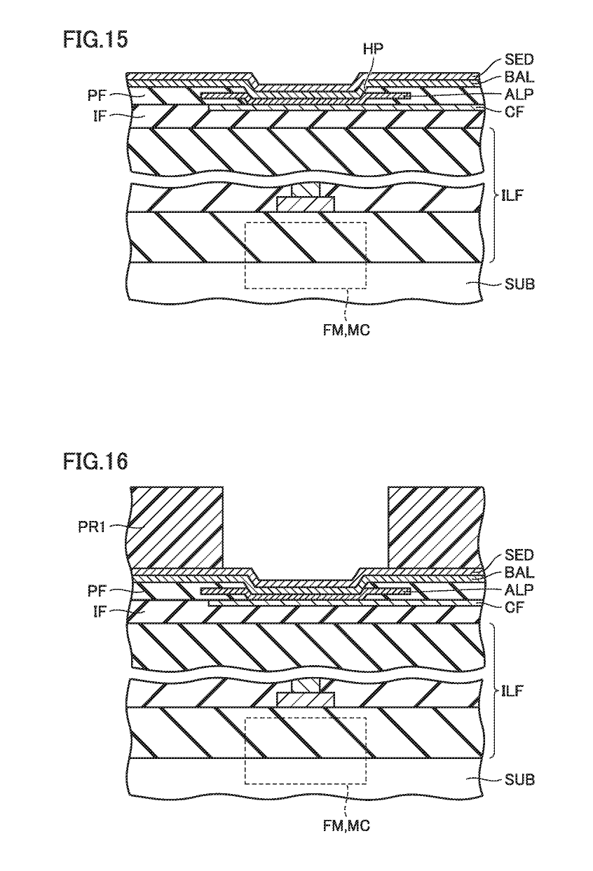

In the semiconductor device of the comparative example, as illustrated in FIG. 14, predetermined photomechanical process and etching process are performed after insulator PF covering aluminum pad ALP is formed, whereby opening HP through which aluminum pad ALP is exposed is formed in insulator PF. Then, as illustrated in FIG. 15, barrier layer BAL is formed so as to be in contact with exposed aluminum pad ALP. Then, seed layer SED is formed so as to be in contact with barrier layer BAL.

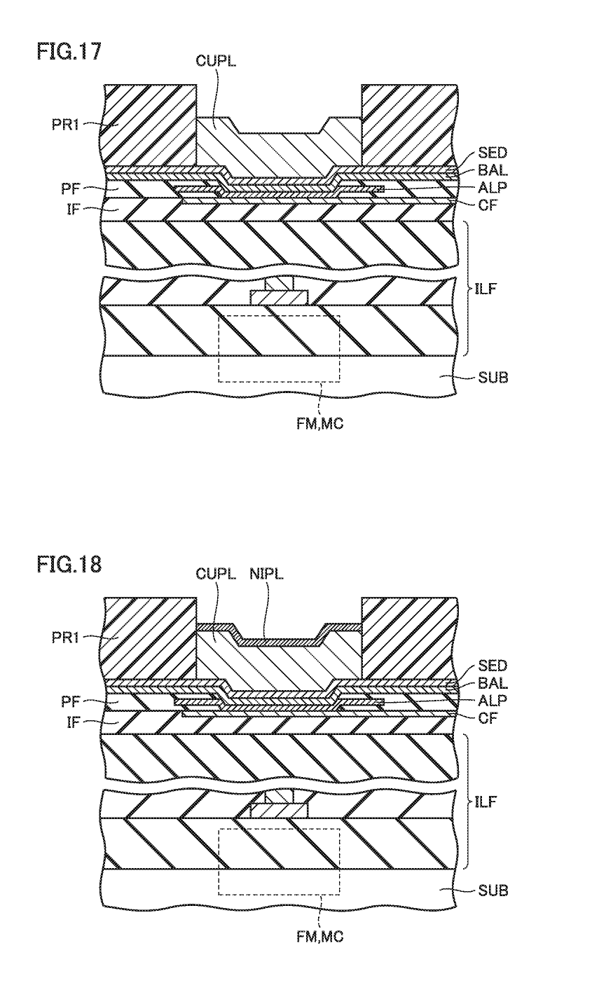

Then, as illustrated in FIG. 16, resist pattern PR1 is formed by performing a predetermined photomechanical process in order to form the copper film. Then, as illustrated in FIG. 17, copper film CUPL is formed by growing copper on the surface of exposed seed layer SED by the electrolytic plating method.

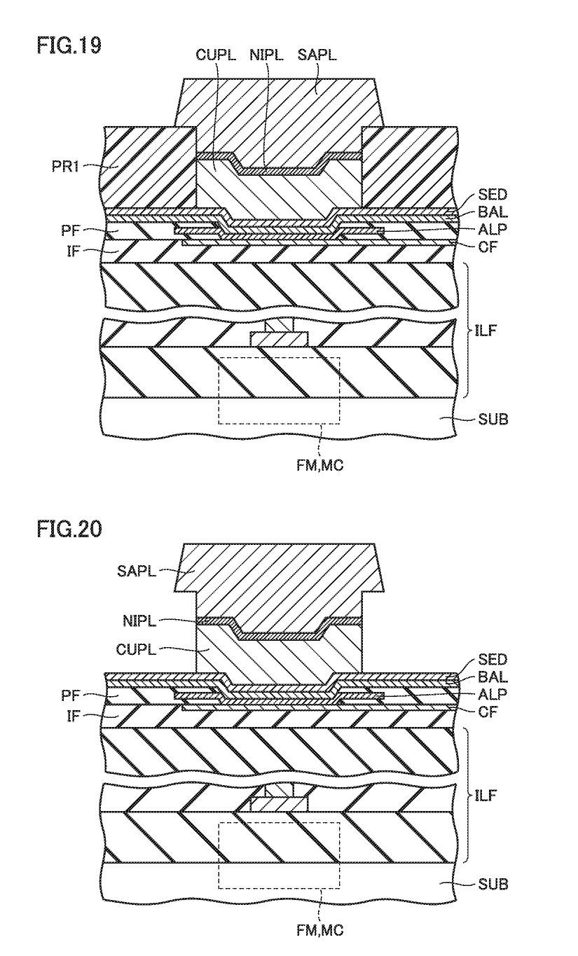

Then, as illustrated in FIG. 18, nickel film NIPL is formed by growing a nickel film on the surface of copper film CUPL by the electrolytic plating method. Then, as illustrated in FIG. 19, a tin silver film SAPL is formed by growing a tin film containing silver on the surface of nickel film NIPL by the electrolytic plating method. The electrolytic plating is continuously performed.

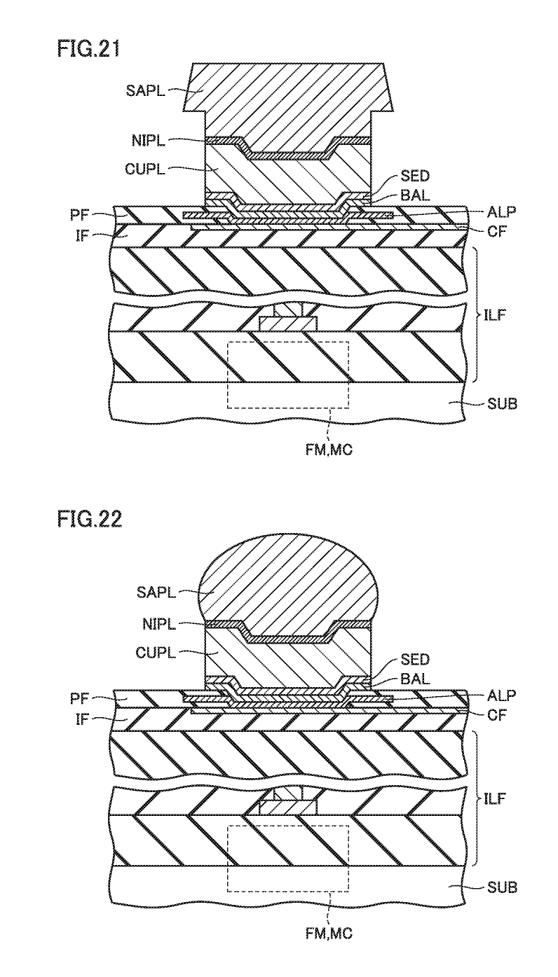

Then, as illustrated in FIG. 20, resist pattern PR1 is removed to expose seed layer SED. Then, as illustrated in FIG. 21, exposed seed layer SED and barrier layer BAL are sequentially removed by the etching process. Then, as illustrated in FIG. 22, by performing a reflow treatment (heat treatment), tin silver film SAPL is dissolved and becomes rounded. Thus, a main part of the semiconductor device of the comparative example is formed.

In the semiconductor device of the comparative example, because the steps from the step of forming copper film CUPL to the step of forming tin silver film SAPL are continuously performed by the electrolytic plating method, when the memory retention test of the flash memory is performed, the memory retention test can only be performed after the reflow treatment is performed on tin silver film SAPL. However, because the memory retention test is performed at a temperature of 250° C., tin silver film SAPL is melted and the memory retention test cannot be performed.

When the wafer test is performed, it is necessary to bring the probe needle into contact with tin silver film SAPL. However, it is difficult to bring the probe needle into contact with rounded tin silver film SAPL. For this reason, it is difficult to surely perform the wafer test.

Compared with the semiconductor device of the comparative example, in the semiconductor device of the first embodiment, tin alloy ball SNB is formed after silver bump AGBP is formed. Consequently, the memory retention test can be performed when silver bump AGBP is formed before tin alloy ball SNB is formed. At this point, the probe needle can be surely brought into contact with silver bump AGBP, and the wafer test can surely be performed.

Silver bump AGBP is bonded to seed layer SED (copper film). Additionally, tin alloy ball SNB bonded to silver bump AGBP contains copper. Therefore, the inventors have studied the heat resistance of a bonded portion (bonded portion A) between silver bump AGBP and seed layer SED and the heat resistance of a bonded portion (bonded portion B) between silver bump AGBP and tin alloy ball SNB.

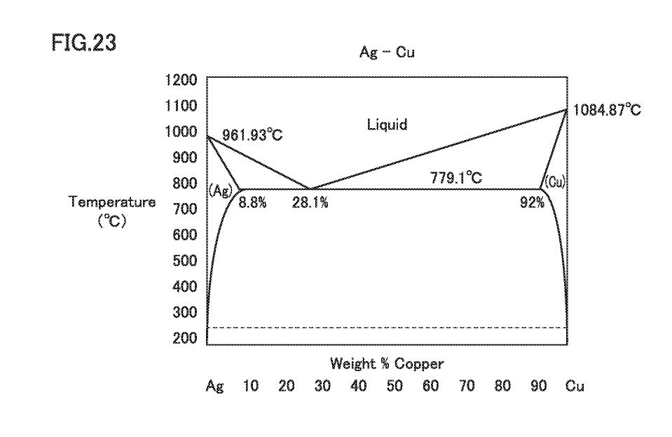

FIG. 23 illustrates a phase diagram of a binary alloy of silver and copper. As illustrated in FIG. 23, the binary alloy of silver and copper is melted at a temperature of about 779° C. On the other hand, the memory retention test is performed at a temperature of about 250° C. The highest temperature is about 150° C. in the temperature cycle test and high temperature exposure test, which are performed after the completion of the semiconductor device. For this reason, it is considered that the heat of the memory retention test or the temperature cycle test has almost no influence on bonded portion A and bonded portion B.

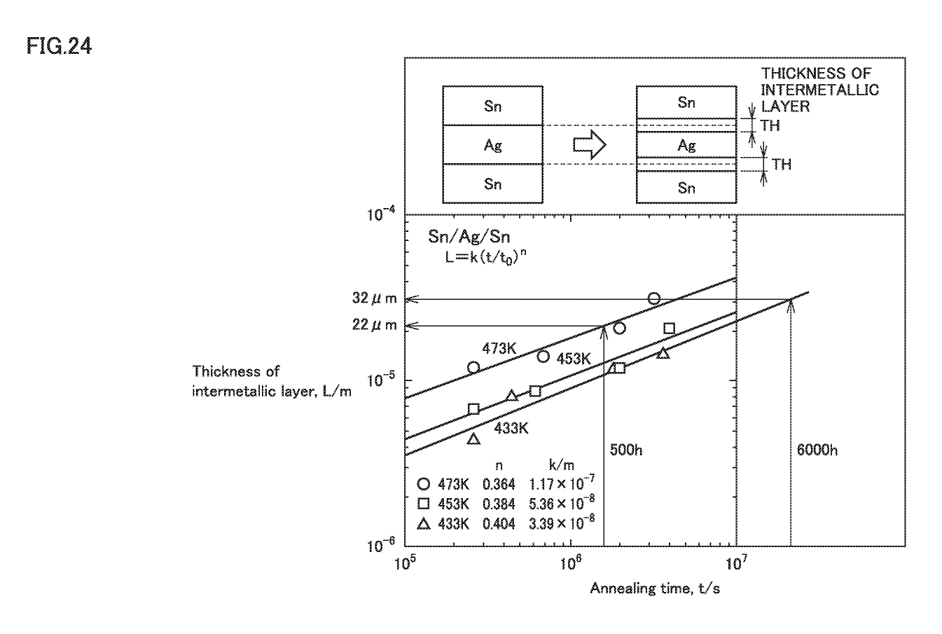

The inventors also studied how much an intermetallic layer of silver and tin is formed in the bonded portion between silver and tin. FIG. 24 illustrates a relationship between an annealing time and the thickness of the intermetallic layer to be formed. A horizontal axis indicates the annealing (heat treatment) time, and a vertical axis indicates the thickness of the intermetallic layer. The graph is a result for a sample (Sn/Ag/Sn) in which the silver film is sandwiched between the tin films. Accordingly, the thickness of the intermetallic layer on the vertical axis indicates the thickness of two layers. For example, when the heat treatment is performed at a temperature of 200° C. (473 K) for 500 hours, the thickness of the intermetallic layer of silver and tin becomes 22 μm (for two layers). When the heat treatment is performed at a temperature of 160° C. (433 K) for 6000 hours, the thickness of the intermetallic layer of silver and tin is 32 μm (for two layers).

In consideration of the high temperature exposure test (160° C., 6000 hours), it was found that silver film AGPL (silver bump AGBP) is preferably formed to have a thickness of 16 μm (32 μm/2) or more.

Sometimes palladium (Pd), gold (Au), or the like may be added to silver bump AGBP in order to prevent oxidation of the surface. The inventors studied how much the intermetallic layer of palladium and tin is formed. Non-Patent Document 2 (Ken Suzuki, et al., “Reactive Diffusion between Ag and Sn at Solid State Temperatures”, Materials Transactions, Vol. 46, No. 5 (2005) pp. 969 to 973) and Non-Patent Document 3 (http://www.geocities.jp/e_kamasai/shiryou/d-base/alloy-diagram.html) were referred to in the study.

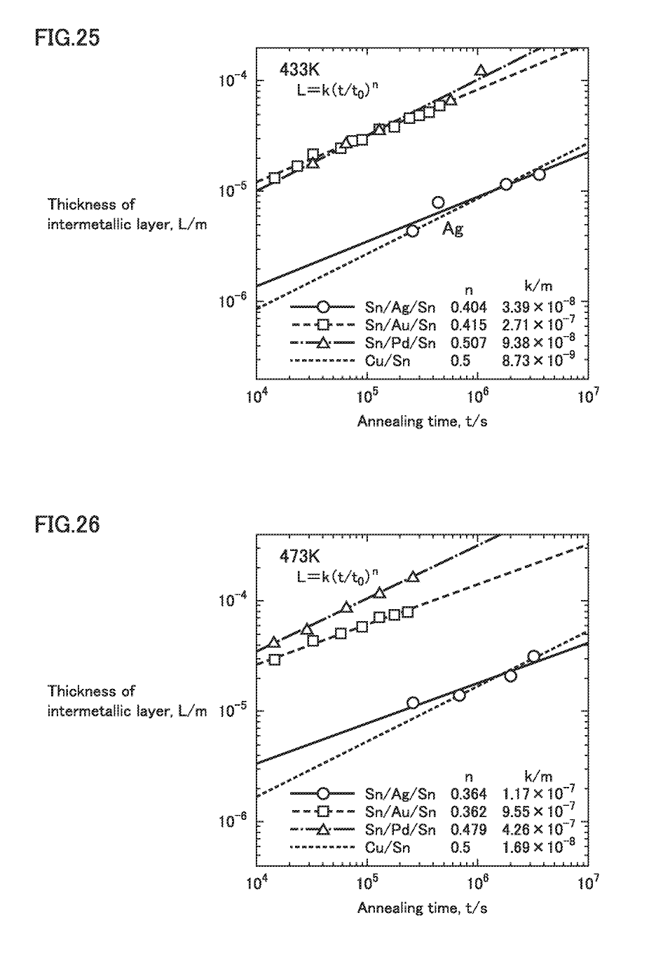

A sample 1 (Sn/Ag/Sn), a sample 2 (Sn/Pd/Sn), a sample 3 (Sn/Au/Sn), and a sample 4 (Cu/Sn) are cited as samples. FIG. 25 illustrates a relationship between the annealing time and the thickness of the intermetallic layer to be formed at a temperature of 160° C. (433 K). A horizontal axis indicates the annealing (heat treatment) time, and a vertical axis indicates the thickness of the intermetallic layer. FIG. 26 illustrates a relationship between the annealing time and the thickness of the intermetallic layer to be formed at a temperature of 200° C. (473 K). A horizontal axis indicates the annealing (heat treatment) time, and a vertical axis indicates the thickness of the intermetallic layer.

As illustrated in FIGS. 25 and 26, for the annealing time of 107 seconds (2778 hours), the thickness of the intermetallic layer formed in sample 1 (Sn/Ag/Sn) is thinner than those in sample 2 (Sn/Pd/Sn) and sample 3 (Sn/Au/Sn) by about one digit. It can also be seen that sample 1 (Sn/Ag/Sn) is somewhat thinner than sample 4 (Cu/Sn).

When the graphs are compared at about 6000 hours while extrapolated (not illustrated), the thickness of the intermetallic layer formed in sample 1 is thinner than the thickness of the intermetallic layer formed in sample 4, and is estimated to be about a half of the thickness of the intermetallic layer formed in sample 4. Thus, it was found that palladium and gold are not very effective as a barrier that prevents the diffusion of tin, but silver is most effective.

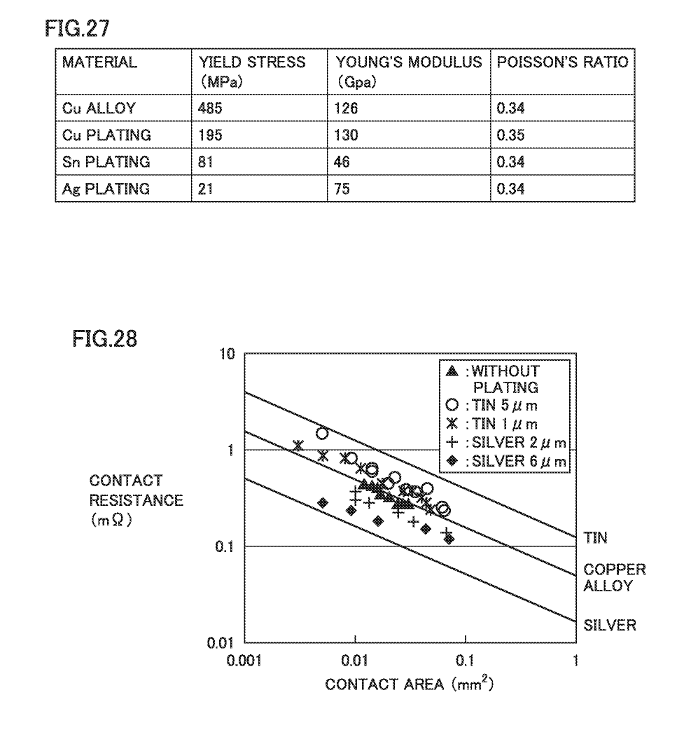

Additionally, silver (silver bump AGBP) is a soft material, and can prevent the influence of stress on an underlying layer. FIG. 27 illustrates a yield stress, a Young's modulus, and a Poisson's ratio of each material (copper alloy, copper plating, tin plating, and silver plating).

As used herein, the yield stress means stress immediately before occurrence of a phenomenon (yielding) in which the stress (tensile load) suddenly decreases during a tensile test and then elongation progresses without increasing the stress. The yield stress of silver (silver bump AGBP) is lower than the yield stress of the copper alloy, the yield stress of the copper plating and the yield stress of the tin plating.

The Poisson's ratio of silver (silver bump AGBP), the Poisson's ratio of the copper alloy, the Poisson's ratio of the copper plating, and the Poisson's ratio of the tin plating are almost the same. As to the Young's modulus that is an index of the hardness of the material, the Young's modulus of silver (silver bump AGBP) is higher than the Young's modulus of the tin plating, and is lower than the Young's modulus of the copper alloy and Young's modulus of the copper plating. Thus, it can be said that in silver bump AGBP, the film stress has a little influence on the underlying layer.

In a standard solder bump, a nickel film may be used as the barrier film. The nickel film has a high film stress. Consequently, if the thickness of the nickel film is increased to secure the heat resistance and the low-k film having weak adhesion and brittleness is formed on the underlying layer, the low-k film can be peeled off from the semiconductor substrate by the film stress (tensile stress) of the nickel film (white bump). On the other hand, in the semiconductor device of the first embodiment, peeling off of the low-k film can be prevented by forming relatively soft silver bump AGBP.

Contact resistance of silver (silver bump AGBP) is lower than contact resistance of copper or the like. FIG. 28 illustrates a relationship between the contact area and the contact resistance. As can be seen from FIG. 28, the contact resistance of silver (silver bump AGBP) is smaller than the contact resistance of copper or the like (solid triangle).

### Second Embodiment

A second example of the semiconductor device including the silver bump and the tin alloy ball as the bump structure will be described below.

In the semiconductor device of the first embodiment, silver bump AGBP is formed by the electrolytic plating method. The case that silver bump AGBP is formed by a printing method will be described below.

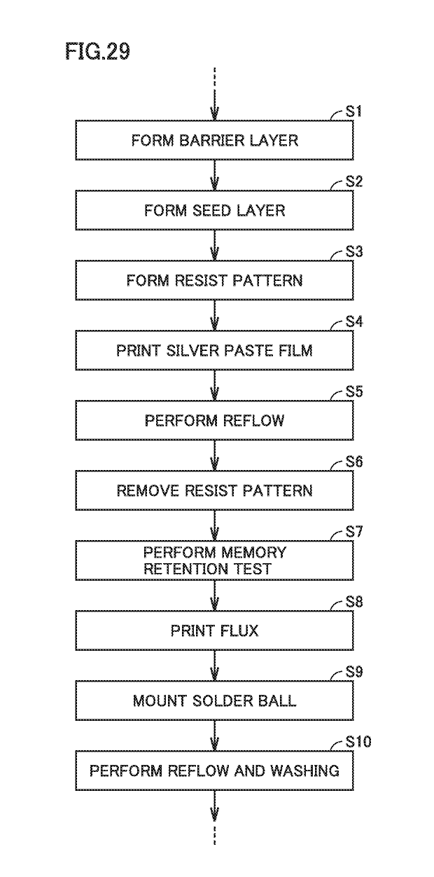

First, a manufacturing flowchart will be explained. First, a structure including the memory cell, the multilayer interconnect structure, the copper wiring, and the aluminum pad is formed on a semiconductor substrate. Then, as illustrated in FIG. 29, in step 51, the barrier layer is formed so as to be in contact with the aluminum pad. Then, in step S2, the seed layer is formed so as to be in contact with the barrier layer.

Then, in step S3, the resist pattern is formed in order to form the silver bump. Then, in step S4, a silver paste film is printed using the resist pattern as a printing mask. Then, in step S5, the reflow process is performed. Then, in step S6, the resist pattern is removed. Then, in step S7, the memory retention test is performed.

Then, in step S8, a flux is printed on the silver paste film. Then, in step S9, the solder ball is mounted on the silver plated film. Then, in step S10, the reflow and the washing are performed. Then, the semiconductor device is completed through a temperature cycle test and a high temperature exposure test.

The semiconductor device manufacturing method will specifically be described below while the sectional structure is illustrated. The same component as that of the semiconductor device of the first embodiment is denoted by the same reference numeral, and the description will be omitted unless necessary.

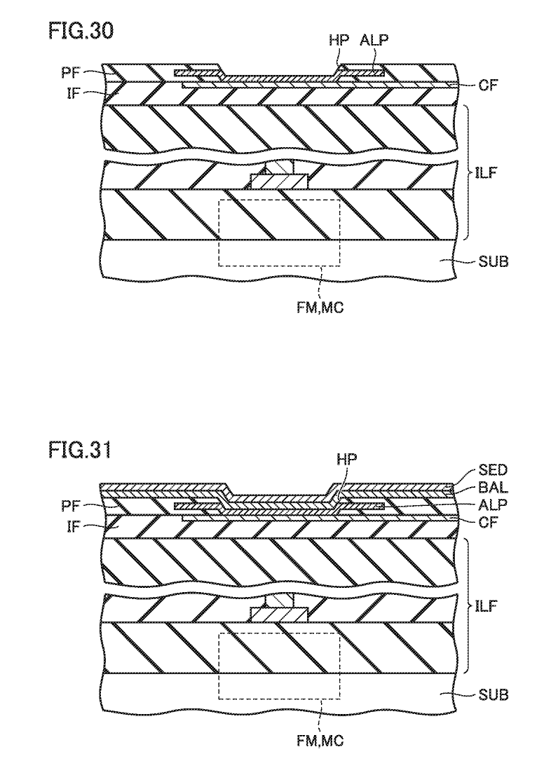

First, as illustrated in FIG. 30, opening HP through which aluminum pad ALP is exposed is formed in insulator PF through the step similar to that in FIG. 5. Then, as illustrated in FIG. 31, barrier layer BAL constructed with the titanium alloy layer (a thickness of about 70 nm or more) is formed so as to be in contact with exposed aluminum pad ALP through the step similar to that in FIG. 6.

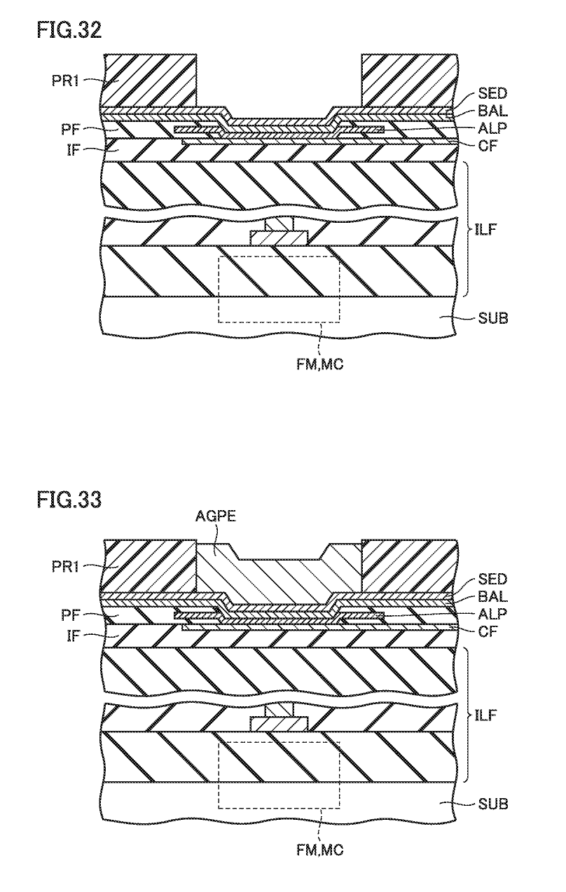

Then, seed layer SED constructed with the copper film is formed so as to be in contact with barrier layer BAL. Then, as illustrated in FIG. 32, resist pattern PR1 that becomes the printing mask is formed through the step similar to that in FIG. 7. Then, as illustrated in FIG. 33, silver film AGPE is formed by applying a silver paste by the printing method. Then, resist pattern PR1 is removed.

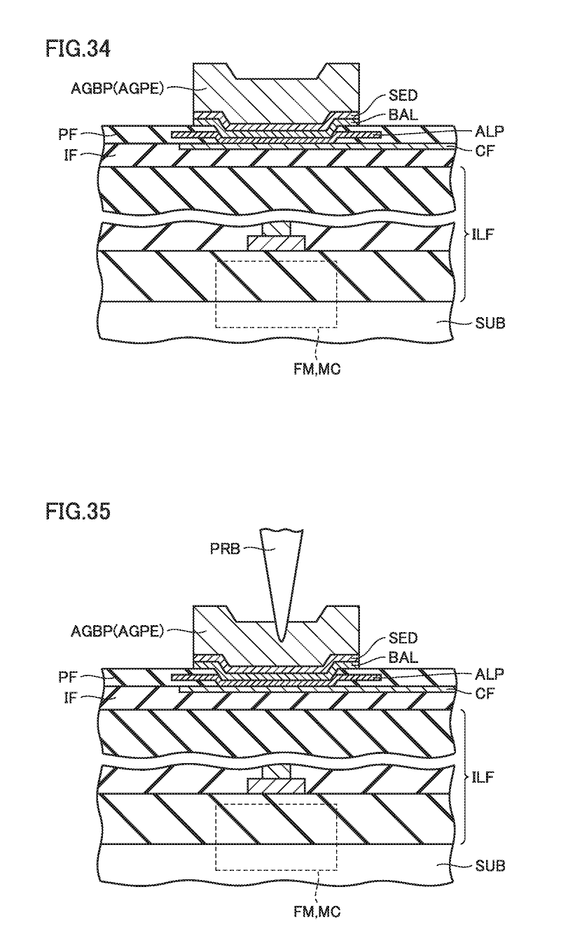

Then, as illustrated in FIG. 34, exposed seed layer SED and barrier layer BAL are sequentially removed through the step similar to that in FIG. 9. Thus, silver bump AGBP constructed with silver film AGPE is formed. Then, similarly to the step in FIG. 10, as illustrated in FIG. 35, the memory retention test of the flash memory is performed while probe needle PRB is brought into contact with silver bump AGBP.

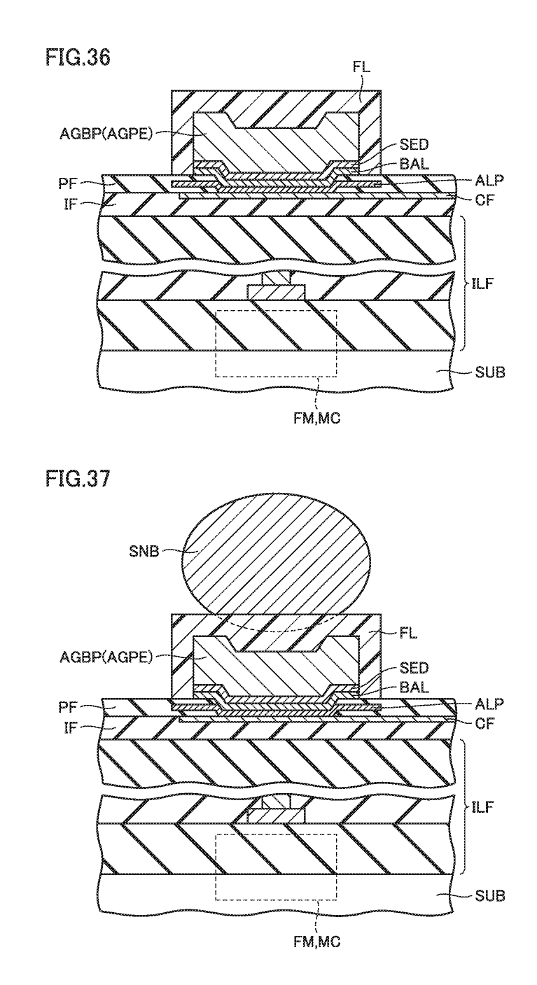

Then, as illustrated in FIG. 36, flux FL is applied so as to cover silver bump AGBP by, for example, the printing method through the step similar to that in FIG. 11. Then, as illustrated in FIG. 37, tin alloy ball SNB (Sn-1.0% Ag-0.5% Cu) is mounted on silver bump AGBP through the step similar to that in FIG. 12.

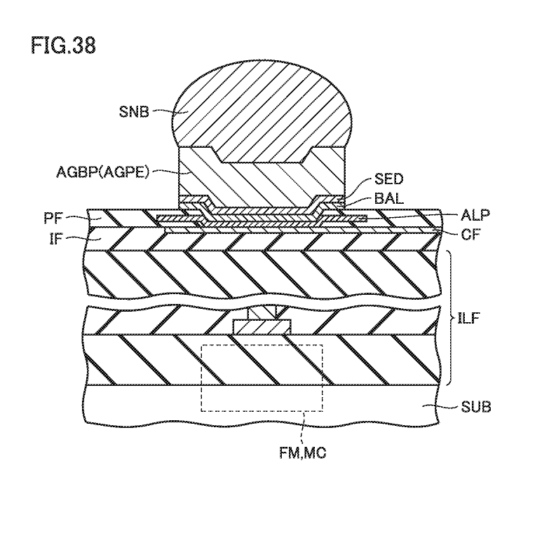

Then, as illustrated in FIG. 38, tin alloy ball SNB is bonded to silver bump AGBP through the step similar to that in FIG. 13. Then, semiconductor substrate SUB including tin alloy ball SNB is washed. Thus, the main part of the semiconductor device is completed. Then, the semiconductor device is subjected to the temperature cycle test and the high temperature exposure test.

In the above-described semiconductor device, silver bump AGBP and tin alloy ball SNB are formed as the bump structure. Silver bump AGBP is formed by printing the silver paste using the resist pattern as the printing mask.

As a result, similarly to the first embodiment, the memory retention test of the flash memory can be performed before tin alloy ball SNB is formed. The heat during the temperature cycle test and the high temperature exposure test has almost no influence on the bonded portion (bonded portion A) between silver bump AGBP and seed layer SED and the bonded portion (bonded portion B) between silver bump AGBP and tin alloy ball SNB. Additionally, diffusion of tin can be effectively prevented by silver bump AGBP. Additionally, the film stress has a little influence on the underlying layer.

The method of forming silver bump AGBP by printing the silver paste is effective when exact pattern accuracy is not required.

### Third Embodiment

A third example of the semiconductor device including the silver bump and the tin alloy ball as the bump structure will be described.

In the semiconductor device of the first embodiment, silver bump AGBP is formed by the electrolytic plating method. The case that silver bump AGBP is formed by a sputtering method will be described below.

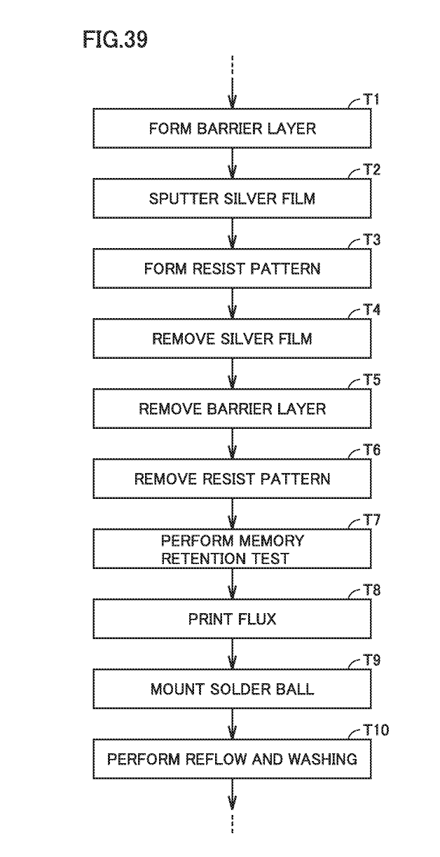

First, a manufacturing flowchart will be explained. First, a structure including the memory cell, the multilayer interconnect structure, the copper wiring, and the aluminum pad is formed on a semiconductor substrate. Then, in step T1, the barrier layer is formed so as to be in contact with the aluminum pad as illustrated in FIG. 39. Then, in Step T2, the silver film is formed so as to cover the barrier layer by the sputtering method.

Then, in step T3, the resist pattern is formed in order to form the silver bump. Then, in step T4, the exposed silver film is removed using the resist pattern as an etching mask. Then, in step T5, the barrier layer is further removed. Then, in step T6, the resist pattern is removed.

Then, in step T7, the memory retention test is performed. Then, in step T8, the flux is printed on the silver sputtered film. Then, in step T9, the solder ball is mounted on the silver sputtered film. Then, in step T10, the reflow and the washing are performed. Then, the semiconductor device is completed through a temperature cycle test and a high temperature exposure test.

The semiconductor device manufacturing method will specifically be described below while the sectional structure is illustrated. The same component as that of the semiconductor device of the first embodiment is denoted by the same reference numeral, and the description will be omitted unless necessary.

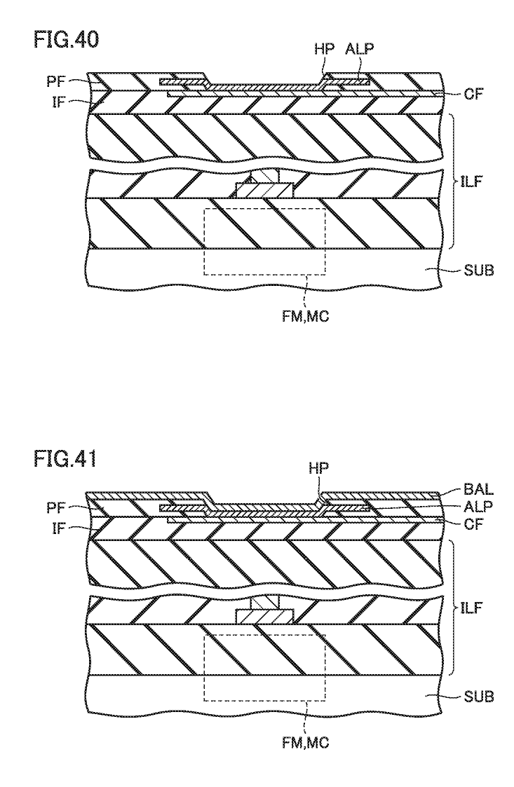

First, as illustrated in FIG. 40, opening HP through which aluminum pad ALP is exposed is formed in insulator PF through the step similar to that in FIG. 5. Then, as illustrated in FIG. 41, barrier layer BAL constructed with the titanium alloy layer (a thickness of about 70 nm or more) is formed so as to be in contact with exposed aluminum pad ALP through the step similar to that in FIG. 6.

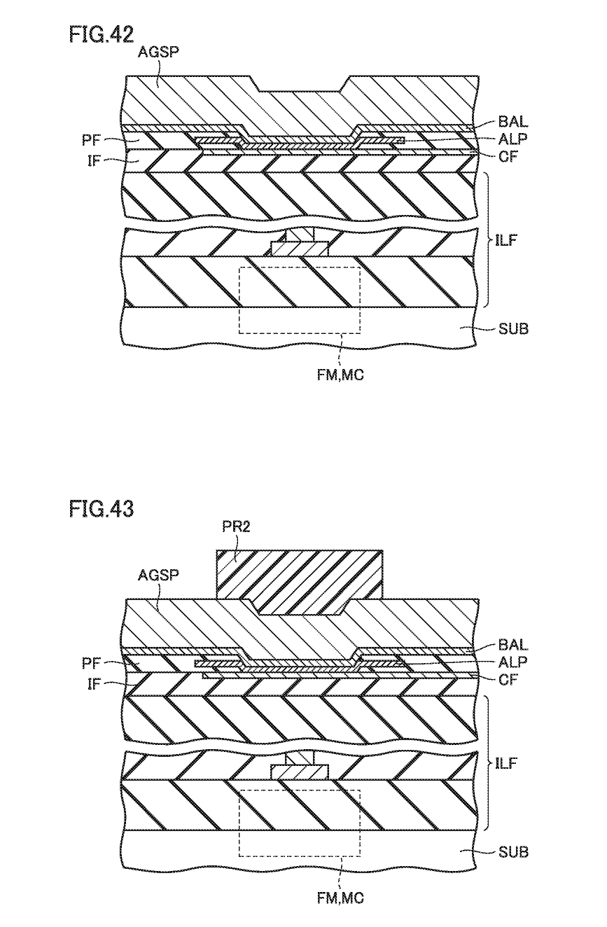

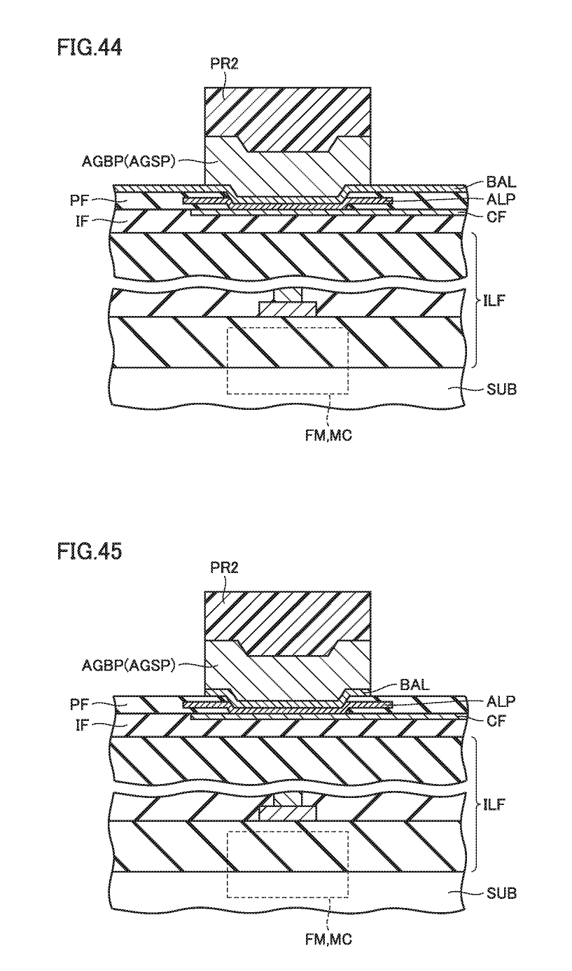

Then, as illustrated in FIG. 42, silver film AGSP is formed by the sputtering method. Then, as illustrated in FIG. 43, resist pattern PR2 is formed by performing a predetermined photomechanical process in order to pattern silver film AGSP. Then, as illustrated in FIG. 44, exposed silver film AGSP is removed using resist pattern PR2 as the etching mask.

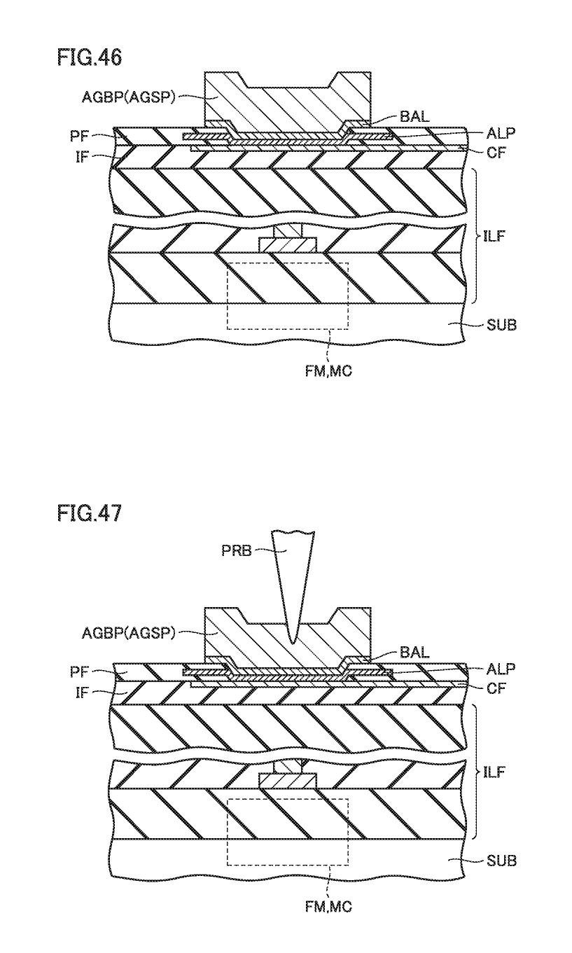

Then, as illustrated in FIG. 45, exposed barrier layer BAL is removed. Then, as illustrated in FIG. 46, resist pattern PR2 is removed. Thus, silver bump AGBP constructed with silver film AGSP is formed. Then, similarly to the step in FIG. 10, as illustrated in FIG. 47, the memory retention test of the flash memory is performed while probe needle PRB is brought into contact with silver bump AGBP.

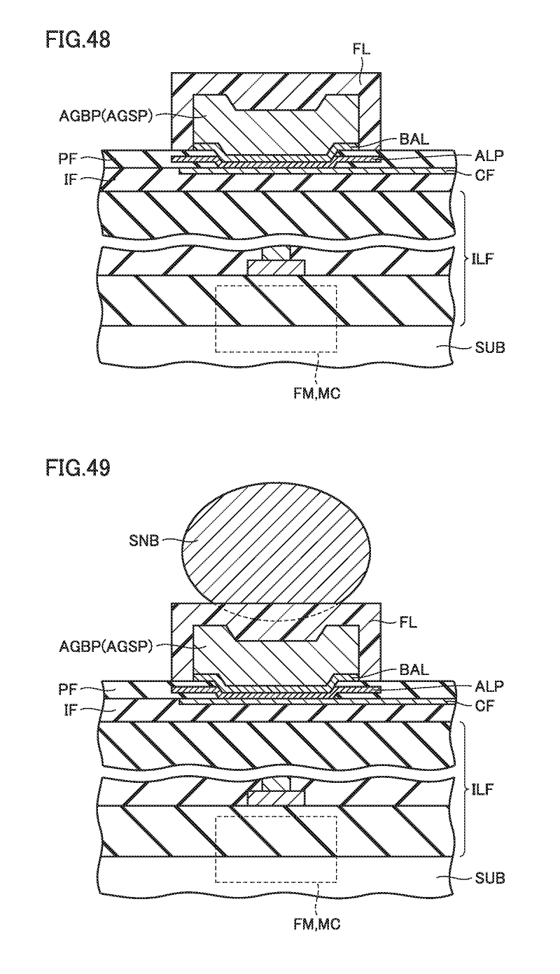

Then, as illustrated in FIG. 48, flux FL is applied so as to cover silver bump AGBP by, for example, the printing method through the step similar to that in FIG. 11. Then, as illustrated in FIG. 49, tin alloy ball SNB (Sn-1.0% Ag-0.5% Cu) is mounted on silver bump AGBP through the step similar to that in FIG. 12.

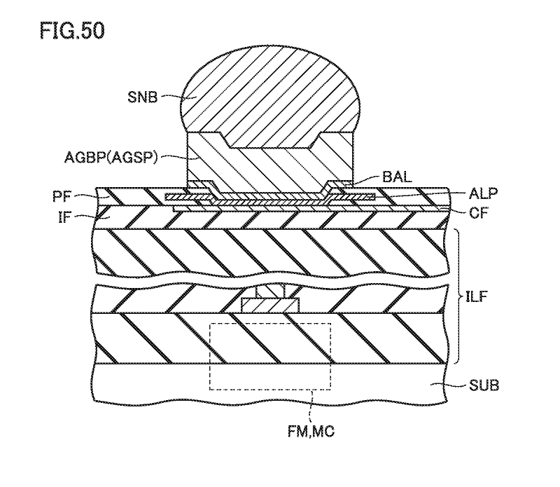

Then, as illustrated in FIG. 50, tin alloy ball SNB is bonded to silver bump AGBP through the step similar to that in FIG. 13. Then, semiconductor substrate SUB including tin alloy ball SNB is washed. Thus, the main part of the semiconductor device is completed. Then, the semiconductor device is subjected to the temperature cycle test and the high temperature exposure test.

In the above-described semiconductor device, silver bump AGBP is formed as the bump structure. Silver bump AGBP is formed by patterning silver film AGSP formed by the sputtering method.

As a result, similarly to the first embodiment, the memory retention test of the flash memory can be performed before tin alloy ball SNB is formed. The heat during the temperature cycle test and the high temperature exposure test has almost no influence on the bonded portion (bonded portion A) between silver bump AGBP and seed layer SED and the bonded portion (bonded portion B) between silver bump AGBP and tin alloy ball SNB. Additionally, diffusion of tin can be effectively prevented by silver bump AGBP. Additionally, the film stress has a little influence on the underlying layer.

In each of the embodiments, the tin alloy ball is applied as the solder bump. Alternatively, the solder bump may be formed by the printing method.

The semiconductor devices and the manufacturing methods thereof described in respective embodiments can be combined in various ways as necessary.

Although the invention made by the inventors has been specifically described based on the embodiments, the present invention is not limited to the above embodiments, but various modifications can be made without departing from the scope of the invention.

What is claimed is:

1. A semiconductor device comprising:
an element formation region defined in a semiconductor substrate;
a semiconductor element formed in the element formation region;
a multilayer interconnect structure formed so as to cover the semiconductor element, the multilayer interconnect structure including a plurality of interconnect layers and an interlayer dielectric electrically insulating the plurality of interconnect layers from each other;
a pad electrode electrically connected to one of the plurality of interconnect layers;
a barrier layer formed so as to be in contact with the pad electrode;
a silver bump electrically connected to the pad electrode with the barrier layer interposed therebetween; and
a solder bump formed so as to be in contact with the silver bump.

2. The semiconductor device according to claim 1, wherein the silver bump is made of a silver alloy containing palladium (Pd) and gold (Au).

3. The semiconductor device according to claim 1, wherein the silver bump is made of pure silver.

4. The semiconductor device according to claim 1, wherein the solder bump is made of a tin alloy containing silver (Ag) and copper (Cu).

5. The semiconductor device according to claim 1, wherein the interlayer dielectric includes a low-k film.

6. The semiconductor device according to claim 1, wherein a seed layer is interposed between the barrier layer and the silver bump.

7. The semiconductor device according to claim 6, wherein the seed layer is constructed with a copper film.

8. The semiconductor device according to claim 1, wherein the barrier layer is constructed with a titanium alloy layer.

9. The semiconductor device according to claim 1, wherein the semiconductor element includes a flash memory.

10. A semiconductor device manufacturing method comprising the steps of:
defining an element formation region in a semiconductor substrate;
forming a semiconductor element in the element formation region;
forming a multilayer interconnect structure so as to cover the semiconductor element, the multilayer interconnect structure including a plurality of interconnect layers and an interlayer dielectric electrically insulating the plurality of interconnect layers from each other;
forming a pad electrode electrically connected to one of the plurality of interconnect layers;
forming a barrier layer such that the barrier layer is in contact with the pad electrode;
forming a silver bump electrically connected to the pad electrode with the barrier layer interposed therebetween; and
forming a solder bump in the silver bump.

11. The semiconductor device manufacturing method according to claim 10, further comprising the step of testing the semiconductor element while performing a heat treatment before the step of forming the solder bump in the silver bump.

12. The semiconductor device manufacturing method according to claim 11, wherein
the step of forming the semiconductor element includes the step of forming a flash memory, and
the step of testing the semiconductor element includes:
the step of bringing a probe needle into contact with the silver bump; and
the step of performing a memory retention test of the flash memory while the probe needle is in contact with the silver bump.

13. The semiconductor device manufacturing method according to claim 10, wherein the step of forming the silver bump includes the step of forming a silver film by electrolytic plating.

14. The semiconductor device manufacturing method according to claim 10, wherein the step of forming the silver bump includes the step of forming a silver film by applying a silver paste by printing.

15. The semiconductor device manufacturing method according to claim 10, wherein the step of forming the silver bump includes the step of forming a silver film by sputtering.

16. The semiconductor device manufacturing method according to claim 10, wherein the step of forming the solder bump includes the step of forming by a solder ball.
